(19) United States
(12) Patent Application Publication
(10) Pub. No.: US 2026/0246439 A1
(43) Pub. Date: Aug. 20, 2026

(54) BULK ACOUSTIC WAVE FILTER

(71) Applicant: STMicroelectronics International N.V., Geneva (CH)

(72) Inventor: Mohamed BOUFNICHEL, Monnaie (FR)

(21) Appl. No.: 19/530,127

(22) Filed: Feb. 4, 2026

(30) Foreign Application Priority Data
Feb. 18, 2025 (FR) 2501664

(51) Int. Cl. H03H 3/02; H03H 9/54

(52) U.S. Cl. CPC H03H 3/02; H03H 9/54; H03H 2003/023

(57) ABSTRACT

The present disclosure relates to a method for manufacturing a bulk acoustic wave filter comprising the consecutive following steps: providing a semiconductor substrate; forming first and second air cavities buried within the semiconductor substrate, the first air cavity being sandwiched between the second air cavity and a top face of semiconductor substrate, and having lateral dimensions smaller than those of second air cavity; and thinning semiconductor substrate by forming trenches surrounding first air cavity and opening into second air cavity.

### CROSS REFERENCE TO RELATED APPLICATIONS

This application claims priority of French Patent Application Number FR2501664, filed February 18, 2025, entitled “Filtre à ondes acoustiques de volume,” the contents of which is incorporated herein by reference in its entirety.

### FIELD OF INVENTION

The present disclosure generally relates to electronic devices, more particularly Bulk Acoustic Wave filters or BAW filters.

### BACKGROUND

Numerous electronic devices comprise at least one bulk acoustic wave filter. For example, such filters are integrated in mobile phones, or smartphones, to avoid the operation of a radio frequency (RF) communications receive channel of the phone to be disturbed by interferences caused by RF signals emitted by other electronic devices, or by noise from outer RF sources.

Two types of bulk acoustic wave filters have already been proposed: the so-called SMR (Solidly Mounted Resonator) filters on one side, and the so-called FBAR (thin-Film Bulk Acoustic Resonator) filters also referred to as “membrane” bulk acoustic wave filters, on the other side. A SMR filter conventionally comprises a membrane made of an insulating material located on, and in contact with, a Bragg mirror, and a piezoelectric layer, located on the membrane, interposed between a bottom electrode and a top electrode. FBAR filters differ from SMR filters mainly in that in the case of FBAR filters, the Bragg mirror is replaced with an air cavity above which the membrane is suspended. Providing the air cavity gives the FBAR filters a better efficiency than that of SMR filters. Indeed, the air cavity provides an acoustic insulation higher than that obtained with a Bragg mirror having several bilayers (around some fifteen bilayers would allow an insulation equivalent to that of an air cavity to be reached, that would be very difficult to implement in practice), resulting in reduced energy losses.

However, existing acoustic wave filters, particularly existing FBAR filters, suffer from various drawbacks. Especially, existing filters are difficult to miniaturize. In existing filters, the stack comprising the bottom electrode, the piezoelectric layer, and the top electrode is formed over a substrate being around several hundred micrometers thick. For

### SUMMARY

There is a need to overcome all or some of drawbacks of the existing bulk acoustic wave filters, especially existing FBAR filters, and the manufacturing method thereof. It would particularly be desirable to reduce the sizes, especially the thickness, of existing filters.

To this end, one embodiment provides a method for manufacturing a bulk acoustic wave filter comprising the consecutive following steps:
a) providing a semiconductor substrate;
b) forming first and second air cavities buried within the semiconductor substrate, the first air cavity being sandwiched between the second air cavity and a top face of semiconductor substrate, and having lateral dimensions smaller than those of second air cavity; and
c) thinning semiconductor substrate by forming trenches surrounding first air cavity and opening into second air cavity.

According to one embodiment, the method further comprises, between steps a) and b), a step for forming, within semiconductor substrate, a first set of first vias and a second set of second vias surrounding the first set of first vias.

According to one embodiment, at step b), first air cavity is formed from first vias and second air cavity is formed from first and second vias.

According to one embodiment, the method comprises, between steps a) and b), the following operations:

forming first and second vias by anisotropically etching semiconductor substrate;

forming a first partially spherical region at the bottom of each via by isotropically etching semiconductor substrate;

extending first and second vias by anisotropically etching semiconductor substrate; and

forming a second partially spherical region at the bottom of each via by isotropically etching semiconductor substrate.

According to one embodiment, the method comprises, between steps a) and b), the following operations:

forming first and second vias by anisotropically etching semiconductor substrate; and

forming a partially spherical region at the bottom of each second via by isotropically etching semiconductor substrate.

According to one embodiment, the method comprises, between steps a) and b), the following operations:

forming first vias by anisotropically etching semiconductor substrate;

forming a first partially spherical region at the bottom of each first via by isotropically etching semiconductor substrate;

extending first vias by anisotropically etching semiconductor substrate;

forming a second partially spherical region at the bottom of each first via by isotropically etching semiconductor substrate;

forming second vias by anisotropically etching semiconductor substrate; and

forming a third partially spherical region at the bottom of each second via by isotropically etching semiconductor substrate.

According to one embodiment, the method further comprises, at step b), forming from each of first and second vias, at least one third air cavity sandwiched between the first and second air cavities.

According to one embodiment, the method further comprises, at step b), forming from each second via, at least one fourth air cavity located within semiconductor substrate, at a depth substantially equal to that of first air cavity.

According to one embodiment, the method further comprises, between steps b) and c), a step for fabricating at least one resonator directly above first air cavity, each resonator comprising an active layer sandwiched between a bottom electrode and a top electrode.

According to one embodiment, at step b), first air cavity and second air cavity are formed by annealing semiconductor substrate under hydrogen atmosphere.

One embodiment provides a bulk acoustic wave filter obtained by the method as described.

According to one embodiment, first air cavity is located, within semiconductor substrate, at a depth of between 300 nm and 1.5 µm.

According to one embodiment, semiconductor substrate has, after thinning, a thickness less than 50 µm, preferably less than 25 µm, more preferably less than 10 µm.

One embodiment provides an electronic device, preferably a mobile phone or smartphone, comprising an RF integrated circuit including at least one filter as described.

### BRIEF DESCRIPTION OF FIGURES

The foregoing features and advantages, as well as others, will be described in detail in the following description of specific embodiments given by way of illustration and not limitation with reference to the accompanying drawings, in which:

FIG. 1 illustrates, with schematic and partial side and section views, steps in an example method for forming cavities in a substrate according to one embodiment;

FIG. 2 illustrates, with schematic and partial side and section views, steps in an example method for forming cavities within a substrate according to one embodiment;

FIG. 3 illustrates, with schematic and partial side and section views, consecutive steps in an example method for forming cavities in a substrate according to one embodiment;

FIG. 4A, FIG. 4B, FIG. 4C, FIG. 4D, FIG. 4E, FIG. 4F, FIG. 4G, FIG. 4H, FIG. 4I, and FIG. 4J schematically and partially illustrate consecutive steps in an example method for manufacturing a bulk acoustic wave filter in a substrate according to one embodiment;

FIG. 5A and FIG. 5B illustrate, with schematic and partial side and section views, consecutive steps in an alternative to the method shown in FIGS. 4A-4J;

FIG. 6A, FIG. 6B, and FIG. 6C illustrate, with schematic and partial side and section views, consecutive steps in an alternative to the method shown in FIGS. 4A-4J;

FIG. 7A and FIG. 7B illustrate, with schematic and partial side and section views, consecutive steps in an alternative to the method shown in FIGS. 4A-4J;

FIG. 8 is a schematic and partial side and section view of an example bulk acoustic wave filter according to one embodiment; and

FIG. 9 schematically and partially illustrates an example electronic device integrating a bulk acoustic wave filter.

### DETAILED DESCRIPTION

Like features have been designated by like references in the various figures. In particular, the structural and/or functional features that are common among the various embodiments may have the same references and may dispose identical structural, dimensional and material properties.

For the sake of clarity, only the operations and elements that are useful for an understanding of the embodiments described herein have been illustrated and described in detail. In particular, integrating bulk acoustic wave filters within different electronic devices likely to implement such filters has not been described in detail, as the described embodiments are compatible with all or most of electronic devices integrating at least one filter, subject to possible adaptations within the capabilities of those skilled in the art based on the present description.

Unless indicated otherwise, when reference is made to two elements connected together, this signifies a direct connection without any intermediate elements other than conductors, and when reference is made to two elements coupled together, this signifies that these two elements can be connected or they can be coupled via one or more other elements.

In the following disclosure, unless indicated otherwise, when reference is made to absolute positional qualifiers, such as the terms “front”, “back”, “top”, “bottom”, “left”, “right”, etc., or to relative positional qualifiers, such as the terms “above”, “below”, “higher”, “lower”, etc., or to qualifiers of orientation, such as “horizontal”, “vertical”, etc., reference is made to the orientation shown in the figures.

Unless specified otherwise, the expressions “around”, “approximately”, “substantially” and “in the order of” signify within 10% or 10°, and preferably within 5% or 5°.

Unless specified otherwise, the terms “insulating” and “conductive” signify electrically insulating and electrically conductive, respectively.

Unless specified otherwise, the expression “in contact” signifies “in mechanical contact”.

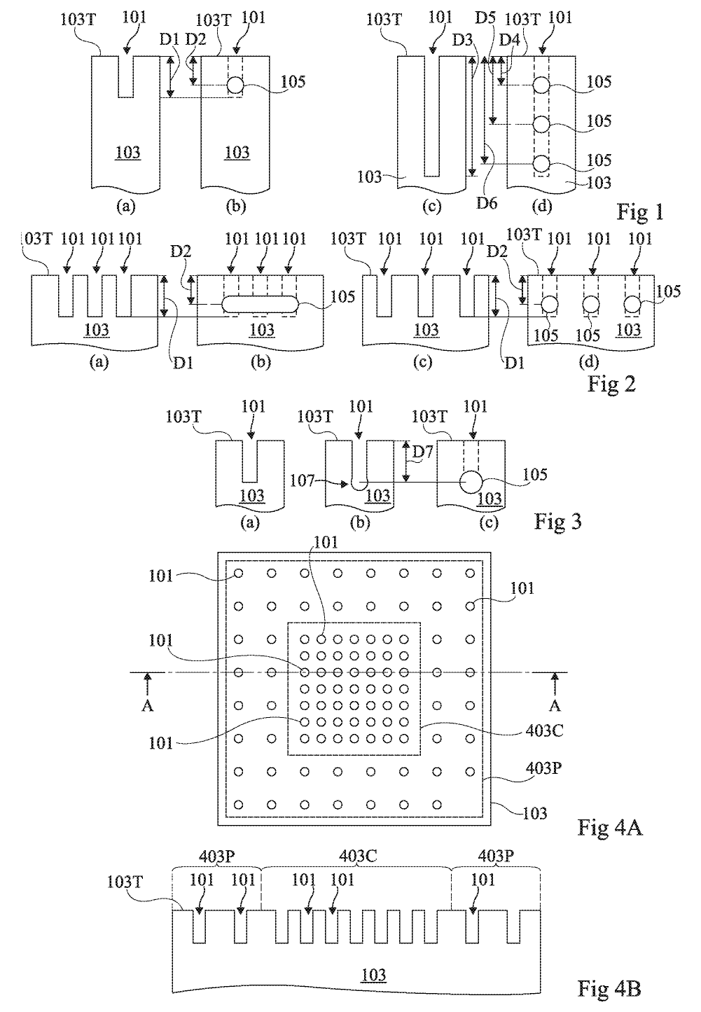

FIG. 1 illustrates, with schematic and partial side and section views, steps in an example method for forming cavities in a substrate according to one embodiment.

FIG. 1 includes a view (a) very schematically showing a structure obtained at the end of a step for forming a via 101 within a semiconductor substrate 103.

By way of example, semiconductor substrate 103 is a wafer or a part of wafer made of a semiconductor material, such as silicon.

In the illustrated example, via 101 extends from a top face 103T of semiconductor substrate 103 to a depth D1 less than the thickness of substrate 103. In this example, via 101 is blind, i.e., it does not reach the side of a bottom face of substrate 103 being opposite the top face 103T.

For example, when viewed from above, via 101 has a substantially square-shaped section. However, this example is not a limitation, as via 101 can more generally have any shape, when viewed from above, for example a polygonal shape other than a square shape — such as rectangular, triangular, hexagonal, etc. — or a rounded shape — such as oval or circular, etc.

For example, via 101 is implemented by photolithography, then etching. To this end, a layer of photosensitive resin (not illustrated) is for example deposited on the side of the top face 103T of semiconductor substrate 103. For example, the photosensitive resin layer coats the whole top face 103T of semiconductor substrate 103, the photosensitive resin layer being for example more precisely located on, and in contact with, the top face 103T of semiconductor substrate 103.

For example, a through hole is then formed within the photosensitive resin layer at the desired location for the future via 101, for example by insolating the photosensitive resin layer through a mask and removing the insolated parts of the photosensitive resin layer in the case of a positive resin, or the non-insolated parts of the photosensitive resin layer in the case of a negative resin. For example, the opening is then extended within semiconductor substrate 103 by etching, for example anisotropic etching of the Reactive Ion Etching (RIE) type, for example by Deep Reactive Ion Etching (DRIE).

For example, the photosensitive resin layer is then entirely removed.

In the illustrated example, the bottom of via 101 is located at the depth D1, i.e., the bottom of via 101 is separated from the top face 103T of semiconductor substrate 103 by a distance D1.

FIG. 1 further includes a view (b) very schematically showing a structure obtained, from the structure shown in view (a), at the end of a subsequent step for annealing semiconductor substrate 103 within which via 101 was previously formed.

In the illustrated example, annealing results in forming a cavity 105 from via 101. For example, annealing is performed at a temperature in the order of 1,000 °C, for example of between 1,000 °C and 1,150 °C. For example, annealing is further performed under hydrogen atmosphere, in the case where semiconductor substrate 103 is made of silicon. Performing annealing under hydrogen allows silicon atoms of semiconductor substrate 103 to have a higher surface mobility than in lack of hydrogen.

Under the action of annealing, silicon atoms of semiconductor substrate 103 reorder so that the structure has a minimum surface roughness and a minimum surface energy without loss of volume. In practice, via 101 tends to flare in bottom part, i.e., in the vicinity of its bottom, and to close in top part, i.e., in the vicinity of the top face 103T of semiconductor substrate 103. Due to these phenomena, via 101 gradually transforms into cavity 105. The bottom of cavity 105 is located, within semiconductor substrate 103, at a depth D2 strictly less than the depth D1 of via 101.

FIG. 1 further includes a view (c) very schematically showing an alternative to the structure shown in view (a).

In structure shown in view (c), via 101 has a depth D3 strictly higher, for example three times higher, than the depth D1 of via 101 of the structure shown in view (a). For example, via 101 shown in view (c) is obtained by implementing a longer step for etching than that allowing via 101 shown in view (a) to be performed.

FIG. 1 further includes a view (d) very schematically showing a structure obtained, from the structure shown in view (c), at the end of a subsequent step for annealing semiconductor substrate 103 within which via 101 was previously formed. For example, the annealing step is implemented in a manner similar to what was described above in relation with view (b).

In the illustrated example, annealing results from via 101, in forming three cavities 105 substantially vertically aligned. The bottom of cavities 105 are, from the shallowest cavity 105 to the deepest cavity 105, respectively located at different depths D4, D5, and D6 within semiconductor substrate 103. In the illustrated example, depth D6 at which the bottom of the deepest cavity 105 is located is strictly less than the depth D3 at which the bottom of via 101 is located. Moreover, depth D4 at which the bottom of the shallowest cavity 105 is located is for example substantially equal to depth D2.

During annealing, via 101 gradually closes from bottom. In this example, cavities 105 are consecutively formed, from the deepest to the shallowest, as via 101 closes under the action of annealing.

As illustrated in FIG. 1, it is thus possible to form, from a same via 101, one or more separate cavities 105 through the thickness of semiconductor substrate 103 depending on the via 101 being more or less deep. Although views (c) and (d) illustrate a case where three cavities 105 are formed from via 101 with a depth D3, this example is not a limitation, and those skilled in the art will be able as an alternative, to adjust the depth of via 101 according to the number of cavities 105 he or she aims to obtain after annealing.

FIG. 2 illustrates, with schematic and partial side and section views, steps in an example method for forming cavities within a substrate according to one embodiment.

FIG. 2 includes a view (a) very schematically showing a structure obtained at the end of a step for forming a plurality of vias 101 within semiconductor substrate 103.

For example, vias 101 are arranged in an array according to rows and columns, rows being for example substantially perpendicular to columns. For example, the array formed by vias 101 has within manufacturing variations, a substantially constant pitch, i.e., a substantially constant center-to-center distance between two neighboring vias 101.

By way of example, vias 101 have substantially same shapes and sizes within manufacturing variations. For example, vias 101 have in particular the same depth, for example depth D1, within manufacturing variations.

FIG. 2 further includes a view (b) very schematically showing a structure obtained, from the structure shown in view (a), at the end of a subsequent step for annealing semiconductor substrate 103 within which vias 101 were previously formed.

In the illustrated example, annealing results in forming a single cavity 105 from vias 101. The bottom of cavity 105 is for example located at depth D2.

FIG. 2 further includes a view (c) very schematically showing an alternative to the structure shown in view (a).

In the structure shown in view (c), vias 101 are arranged as an array having a pitch strictly higher, for example once and a half higher, than the pitch of the array formed by the vias 101 of the structure shown in view (a). For example, vias 101 shown in view (c) are obtained by implementing a photolithography step using a mask having openings more distant from each other than those allowing vias 101 shown in view (a) to be performed, followed with an etching step.

FIG. 2 further includes a view (d) very schematically showing a structure obtained, from the structure shown in view (c), at the end of a subsequent step for annealing semiconductor substrate 103 within which vias 101 were previously formed. For example, the annealing step is implemented in a similar manner as what was hereinabove described in relation to view (b).

In the illustrated example, annealing results, from vias 101, in forming several cavities 105 (three cavities 105 in the example illustrated) substantially horizontally aligned. In this example the bottoms of cavities 105 are located at substantially same depths, for example substantially equal to depth D2, in semiconductor substrate 103.

During annealing, vias 101 gradually close by forming separate cavities 105.

As illustrated in FIG. 2, it is thus possible to form, from several vias 101, one or more separate cavities 105 within the thickness of semiconductor substrate 103 depending on whether vias 101 are close or distant from each other. Although views (c) and (d) illustrate a case where three cavities 105 are formed from three vias 101, this example is not a limitation, and those skilled in the art will be able, as an alternative, to adjust the number of vias 101 and the spacing between vias 101 according to the number of cavities 105 she or he aims to obtain after annealing. By way of example, there is a threshold of distance between two neighboring vias 101, having substantially same depths, below which the two vias 101 form after annealing a single cavity 105, and over which annealing results in obtaining two separate cavities 105.

By way of example, those skilled in the art will be able in order to perform the steps hereinabove disclosed in relation with FIGS. 1 and 2, to take advantage from the publication by I. Mizushima et al. titled “Empty-space-in-silicon technique for fabricating a silicon-on-nothing structure” published in November 2000 in the review Applied Physics Letters.

FIG. 3 illustrates, with schematic and partial side and section views, consecutive steps in an example method for forming cavities in a substrate according to one embodiment.

FIG. 3 includes a view (a) very schematically showing a structure obtained at the end of a step for forming a via 101 within semiconductor substrate 103.

For example, the step for forming via 101 is implemented in a manner similar to, or same as, what was hereinabove described in relation with view (a) shown in FIG. 1.

FIG. 3 further includes a view (b) very schematically showing a structure obtained, from the structure shown in view (a), at the end of a subsequent step for isotropically etching via 101 previously formed within semiconductor substrate 103.

By way of example, isotropically etching is implemented by exposing the structure to sulfur hexafluoride (SF₆).

In the illustrated example, isotropically etching results in forming a partially spherical region 107 at the bottom of via 101. It comes from the fact that the step before forming via 101 results in passivating its sidewalls, but not its bottom. Thereby, the step for isotropically etching acts only, or mainly, at the lower part of via 101, i.e., at the bottom of via 101.

FIG. 3 further includes a view (c) very schematically showing a structure obtained, from the structure shown in view (b), at the end of a subsequent step for annealing semiconductor substrate 103 within which via 101 was previously formed.

For example, the annealing step is implemented in a manner similar to, or same as, what was hereinabove described in relation with view (b) shown in FIG. 1.

In the illustrated example, annealing results in forming a cavity 105 from via 101. In this example, the gravity center 105 is located within semiconductor substrate 103, at a depth D7 substantially equal to that of the center of the partially spherical region 107 obtained during the step before isotropically etching. Moreover, the cavity 105 obtained after annealing from via 101 being submitted to the step for isotropically etching has a volume strictly higher than that of the cavity 105 obtained after annealing from via 101 being not submitted to the step for isotropically etching (for example, cavity 105 of view (b) shown in FIG. 1).

As illustrated in FIG. 3, it is thus possible to set or freeze, by isotropically etching via 101, the location the cavity 105 obtained after the subsequent annealing step. Isotropically etching further allows the volume of cavity 105 obtained at the end of annealing.

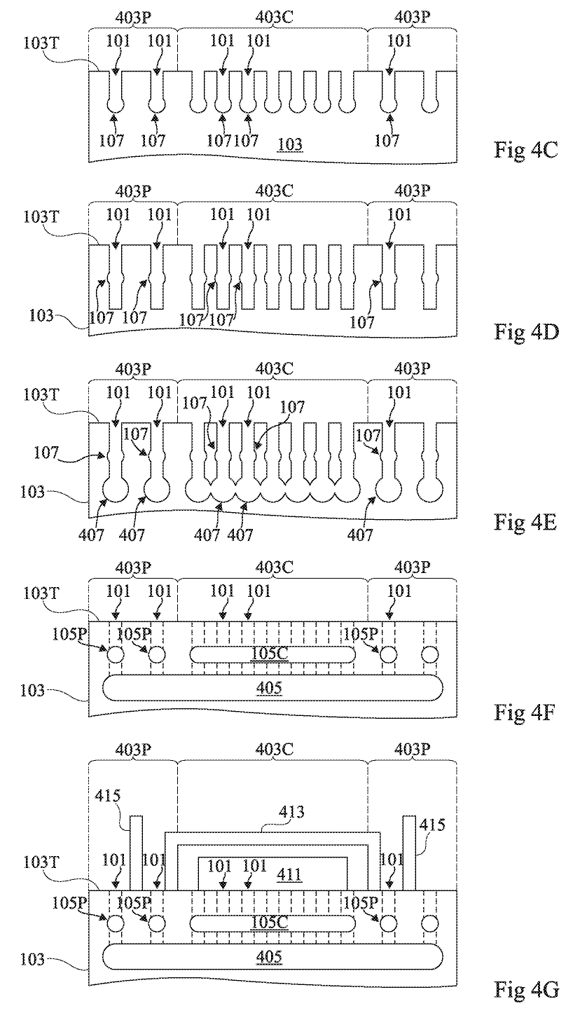

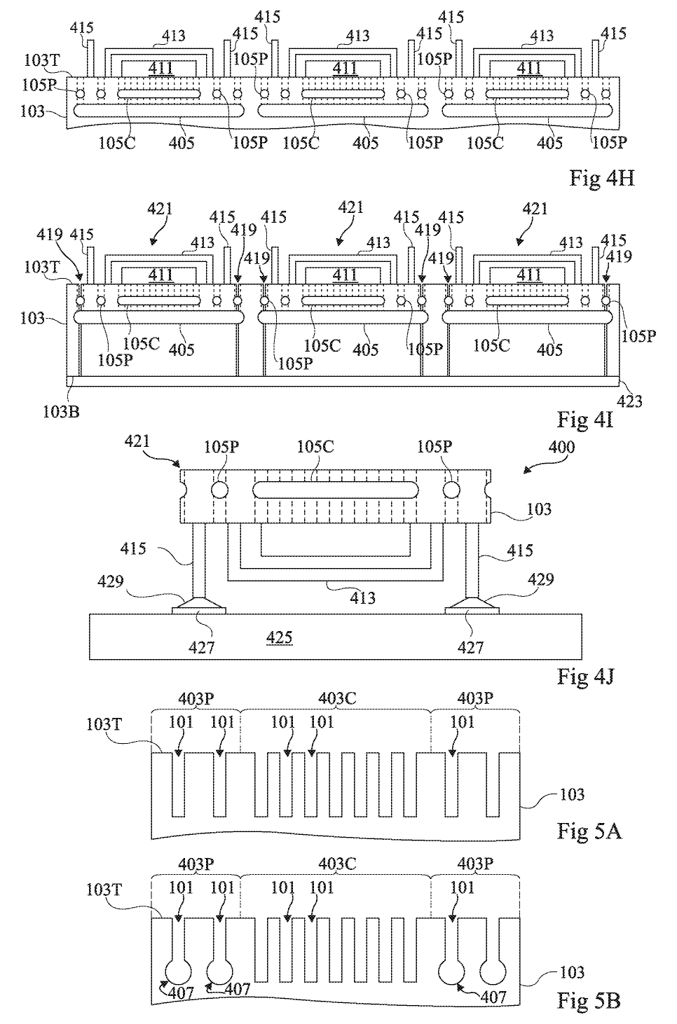

FIG. 4A, FIG. 4B, FIG. 4C, FIG. 4D, FIG. 4E, FIG. 4F, FIG. 4G, FIG. 4H, FIG. 4I, and FIG. 4J schematically and partially illustrate consecutive steps in an example method for manufacturing a bulk acoustic wave filter 400 according to one embodiment.

FIG. 4A is a schematic and partial top view illustrating a step for forming a plurality of vias 101 within semiconductor substrate 103. FIG. 4B is a side and section view according to the plane AA shown in FIG. 4A.

In the illustrated example, vias 101 have shapes and sizes being substantially the same, within manufacturing variations. For example, vias 101 have in particular the same depth, within manufacturing variations. By way of example, the bottom of each via 101 of the structure shown in FIG. 4A is located substantially at depth D1.

In the illustrated example, the structure comprises a first set 403C, or center set 403C, of vias 101, and a second set 403P, or peripheral set 403P, of vias 101 surrounding the first set 403C of vias 101. In the illustrated example, vias 101 being part of the center set 403C are arranged according to an array. Further, in this example, vias 101 being part of the peripheral set 403P are arranged according to an array. In the illustrated example, the array formed by the vias 101 of peripheral set 403P has a pitch strictly higher than the pitch of the array formed by the vias 101 of center set 403C.

For example, the pitch of the array formed by the vias 101 of center set 403C and the pitch of the array formed by the vias 101 of peripheral set 403P are higher than the threshold of the distance between two neighboring vias 101 from which a subsequent step of annealing results in obtaining two separate cavities 105.

The step for forming vias 101 is for example implemented in a manner similar to, or same as, what was hereinabove described in relation with view (a) shown in FIG. 1. Especially, vias 101 are for example formed by photolithography, then anisotropically etching, such as of RIE or DRIE type.

FIG. 4C is a schematic and partial side and section view illustrating a subsequent step for isotropically etching vias 101.

In a manner similar to what was previously described in relation to view (b) shown in FIG. 3, isotropically etching results, in the illustrated example, in forming the partially spherical region 107 at the bottom of each via 101. In the illustrated example, regions 107 are substantially located at the same depth within the semiconductor substrate 103.

FIG. 4D is a schematic and partial side and section view illustrating a subsequent step for anisotropically etching vias 101.

In the illustrated example, vias 101 are extended within semiconductor substrate 103, for example by photolithography, then etching. By way of example, the same etching mask as what was used to form vias 101 during the step previously described in relation with FIGS. 4A and 4B can be used to extend vias 101. For example, etching is similar to, or same as, that hereinabove described in relation with view (a) shown in FIG. 1.

At the end of this step, each via 101 has a depth strictly higher than depth D1, for example equal to around twice depth D1.

FIG. 4E is a schematic and partial side and section view illustrating a subsequent step for isotropically etching vias 101.

In a manner similar to what was previously described in relation with FIG. 4C, isotropically etching results, in the illustrated example, in forming a partially spherical region 407 at the bottom of each via 101. In the illustrated example, each region 107 previously formed during the step hereinabove described in relation with FIG. 4C is sandwiched between the top face 103T of semiconductor substrate 103 and the region 407 located at the bottom of each via 101. In the illustrated example, regions 107 located at the bottom of each via 101 are substantially located at the same depth within semiconductor substrate 103.

For example, regions 407 have lateral dimensions — for example diameter in the case where regions 407 are substantially spherically shaped — strictly higher than that of regions 107. By way of example, regions 407 are obtained by implementing an etching step longer than that allowing regions 107 to be performed. Performing regions 407 does not substantially change the sizes of regions 107. For example, it comes from the fact that the step prior to extending vias 107 results in passivating their sidewalls, including the regions 107, but not their bottoms.

FIG. 4F is a schematic and partial side and section view illustrating a subsequent step for annealing semiconductor substrate 103.

For example, annealing step is implemented in a manner similar to, or same as, what was hereinabove described in relation with view (b) shown in FIG. 1.

In the illustrated example, annealing results in obtaining a single cavity 105C from regions 107 of vias 107 being part of center set 403C, and several separate cavities 105P from regions 107 of vias 101 being part of peripheral set 403P. Further, in this example, annealing results in obtaining, from regions 407, a single cavity 405. Cavity 405 is more precisely formed from regions 407 of vias 101 being part of center set 403C, a single cavity 105C, and, from regions 407, vias 101 being part of peripheral set 403P. In the illustrated example, cavities 105C and 405 are superimposed over each other, cavity 405 being located directly above cavity 105C, and having lateral dimensions strictly higher than those of cavity 105C.

For example, each of cavities 105C, 105P, 405 is an air cavity buried, or embedded, within semiconductor substrate 103. Thus, each cavity 105C, 105P, 405 is wholly included within semiconductor substrate 103, each cavity being fully closed.

In the illustrated example, each cavity 105C, 105P, 405 is wholly bordered by the material of semiconductor substrate 103. In this example, each cavity 105C, 105P is separated from the top face 103T of semiconductor substrate 103 by a part of semiconductor substrate 103. For example, each cavity 105C, 105P is located at a depth of between a few hundred nanometers and a few micrometers under the top face 103T of semiconductor substrate 103. In other words, the top face of each cavity 105C, 105P is separated from the top face of semiconductor substrate 103 by a part of substrate 103 having for example a thickness of between a few hundred nanometers and a few micrometers. The thickness of the part of substrate 103 sandwiched between the top face of each cavity 105C, 105P and the top face 103T of substrate 103 is for example more precisely of between 300 nm and 1.5 µm.

In this example, cavity 405 is separated from cavities 105C, 105P by a part of semiconductor substrate 103. For example, cavity 405 is located at a depth substantially depth equal to twice the depth at which cavities 105C and 105P are located.

In the illustrated example, cavities 105C and 405 comprise each rounded or curved sidewalls, for example sidewalls being concavely shaped. By way of example, each sidewall of cavity 105C, 405 is, when viewed in section, circular arc shaped, such as semi-circularly shaped. In the illustrated example, each cavity 105P is a substantially spherically shaped.

For example, when viewed from above, each cavity 105C, 405 is rectangularly shaped. This example is however not a limitation, as each cavity 105C, 405 could more generally be, when viewed from above, of any shape, for example the shape of a polygon other than rectangle — such as square, triangle, hexagon, etc. — or a rounded shape — for example oval, circle, etc.

FIG. 4G is a schematic and partial side and section view illustrating a subsequent step for forming, on the face 103T of semiconductor substrate 103, a resonator 411, a cover 413 for protecting the resonator 411, and two conductive pillars 415.

In the illustrated example, resonator 411 is located on, and in contact with, the top face 103T of semiconductor substrate 103. Resonator 411 is located directly above cavity 105C previously formed from cavities 107 of the vias 101 of center set 403C. In this example, resonator 411 does not laterally extend directly above cavities 105P previously formed from cavities 107 of the vias 101 of peripheral set 403P.

In the illustrated example, protection cover 413 is supported over the top face 103T of semiconductor substrate 103, and surrounds resonator 411.

In the illustrated example, conductive pillars 415 are located either side of cover 413. For example, each pillar 415 is supported over a part of the top face 103T of semiconductor substrate 103 being directly above cavities 105P.

FIG. 4H is an overall view of semiconductor substrate 103 within and on which were performed several structures (three structures, in the illustrated example) similar to, or same as, that shown in FIG. 4G.

FIG. 4I is a schematic and partial side and section view illustrating a subsequent step for forming trenches 419 laterally demarcating a plurality of semiconductor chips 421.

In the illustrated example, trenches 419 vertically extend through the whole thickness of semiconductor substrate 103, from its top face 103T to its bottom face 103B. Trenches 419 could be formed by plasma etching, sawing, or any other appropriate cutting method.

In the illustrated example, a substrate 423 for temporary supporting, for example a film, is used to mechanically sustain chips 421 during, and at the end of, the cutting step.

Each trench 419 laterally surrounds one of the semiconductor chips 421. For example, when viewed from above, each trench has a rectangular, square, etc. shape. Each trench 419 laterally surrounds cavity 105C of the semiconductor chip 421. Trenches 419 are performed so as to open within cavity 405. Thereby, for each semiconductor chip 421, a part of semiconductor substrate 103 sandwiched between cavity 405 and overlaying resonator 411 is exposed. Semiconductor substrate 103 is thus thinned, each semiconductor chip 421 comprising a portion of semiconductor substrate 103 having a thickness substantially equal to the depth of cavity 405, for example a thickness in the order of a few micrometers, e.g. of between 3 and 5 µm.

FIG. 4J is a schematic and partial side and section view illustrating a subsequent step for attaching one of the semiconductor chips 421 to the top face of a transfer substrate 425.

During this step, one of the semiconductor chips 421 shown in FIG. 4I is for example flipped so as to place conductive pillars 415 of chip 421 opposite corresponding connecting metal pads 427 of transfer substrate 425. Conductive pillars 415 and opposite pads 427 are then attached and electrically connected, for example by soldering, by means of microtubes, or any other appropriate method. In the illustrated example, brazing bumps 429 are used to electrically connect and mechanically assemble pillars 415 onto pads 427.

At the end of the steps hereinabove described in relation with FIGS. 4A-4J, bulk acoustic wave filter 400 is obtained.

According to one embodiment, filter 400 comprises air cavity 105C embedded within semiconductor substrate 103; resonator 411 located directly above air cavity 105C; and several air cavities 105P embedded within semiconductor substrate 103, and located in the vicinity of air cavity 105C.

Although FIGS. 4A-4J consider as an example a case where a single resonator 411 is located directly above air cavity 105C, this example is not a limitation, and those skilled in the art will be able, based on the provisions of the present description, to provide several resonators same as, or similar to, resonator 411 being located directly above cavity 105C. Moreover, although FIG. 4J considers as an example a case where filter 400 comprises several cavities 105P, this example is not a limitation, as filter 400 could alternatively comprise a single cavity 105P, for example a cavity 105P with a ring shape laterally surrounding cavity 105C, or be free of cavity 105P.

Moreover, although FIGS. 4A-4E illustrate a case where the different steps for etching the vias 101 being part of set 403C and the vias 101 being part of set 403P are concurrently performed, this example is not a limitation, and the different steps for etching vias 101 could be performed successively for sets 403C and 403P.

FIG. 5A and FIG. 5B illustrate, with schematic and partial side and section views, consecutive steps in an alternative to the method shown in FIGS. 4A-4J.

FIG. 5A is a schematic and partial side and section view illustrating a step for forming a plurality of vias 101 within semiconductor substrate 103.

In the illustrated example, vias 101 have substantially same shapes and sizes, within manufacturing variations. For example, vias 101 have in particular the same depth, within manufacturing variations. By way of example, the structure shown in FIG. 5A differs from that shown in FIGS. 4A and 4B in that vias 101 of the structure shown in FIG. 5A have a depth higher than that of vias 101 of the structure shown in FIGS. 4A and 4B. By way of example, the bottom of each via 101 of the structure shown in FIG. 5A is located at a depth of between depth D1 and depth D3, for example at a depth allowing, after annealing, two cavities to be formed from each via 101.

FIG. 5B is a schematic and partial side and section view illustrating a subsequent step for isotropically etching the vias 101 being only part of peripheral set 403P.

In a similar manner to what was previously described in relation with FIG. 4E, isotropically etching results in the illustrated example, in forming partially spherical region 407 at the bottom of each via 101 of peripheral set 403P. In the illustrated example, regions 407 are substantially located at the same depth within semiconductor substrate 103.

Although it was not described in detail, subsequent steps similar to, or same as, those previously described in relation with FIGS. 4F-4J are for example implemented from the structure shown in FIG. 5B. Implementing these steps results in obtaining a bulk acoustic wave filter having a structure similar to that of filter 400 hereinabove described in relation with FIG. 4J.

Among these steps, a step for annealing under hydrogen similar to, or same as, that hereinabove described in relation with FIG. 4F results especially in forming within semiconductor substrate 103, cavities similar to cavities 105C, 105P, and 405 of the structure shown in FIG. 4F.

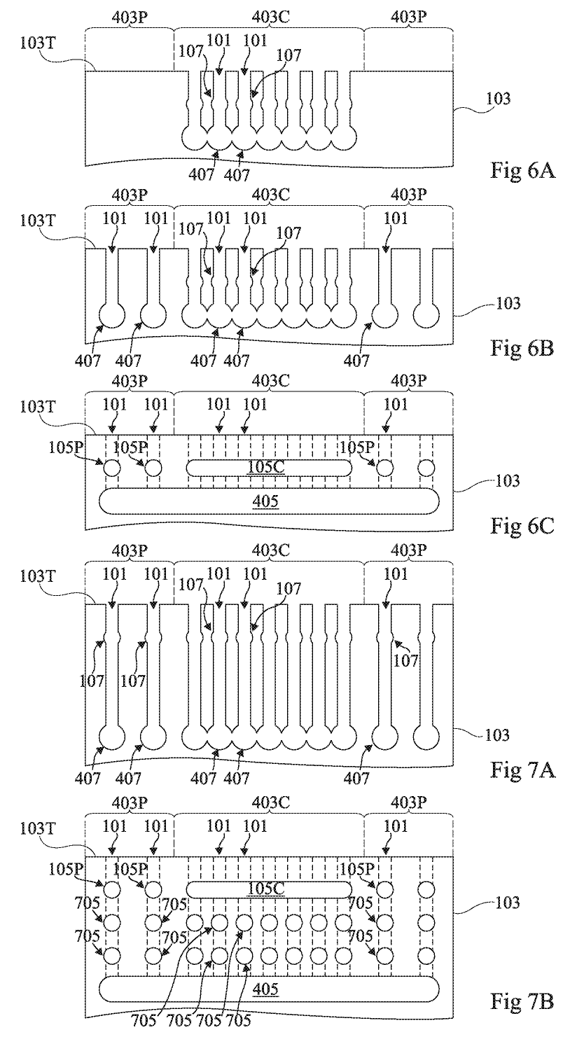

FIG. 6A, FIG. 6B, and FIG. 6C illustrate, with schematic and partial side and section views, consecutive steps in an alternative to the method shown in FIGS. 4A-4J.

FIG. 6A is a schematic and partial side and section view illustrating a step for forming the vias 101 being part of only center set 403C.

For example, the vias 101 of center set 403C are formed in a manner similar to, or same as, what was previously described in relation with FIGS. 4A-B. By way of example, the bottom of each via 101 of center set 403C of the structure shown in FIG. 6A is located at depth D1.

FIG. 6A further illustrates a subsequent step for anisotropically etching the vias 101 of center set 403C, followed with steps for isotropically etching and then anisotropically etching these vias, for example in a manner similar to, or same as, what was hereinabove described in relation with FIGS. 4D and 4E.

The structure illustrated in FIG. 6A differs for example from that shown in FIG. 4E in that it is devoid of the vias 101 being part of peripheral set 403P.

FIG. 6B is a schematic and partial side and section view illustrating a subsequent step for forming the vias 101 being part of peripheral set 403P, followed with a step for isotropically etching these vias, for example in a manner similar to, or same as, what was hereinabove described in relation with FIGS. 5A and 5B as regards the vias 101 being part of peripheral set 403P.

FIG. 6C is a schematic and partial side and section view illustrating a subsequent step for annealing semiconductor substrate 103. The annealing step is for example implemented in a manner similar to, or same as, what was hereinabove described in relation with FIGS. 4F.

In the illustrated example, annealing results in obtaining cavity 105C from regions 107 of the vias of center set 403C, and several separate cavities 105P from regions 107 of the vias of peripheral set 403P. Further, in this example, annealing results in obtaining cavity 405 from regions 107 of the vias 101 of peripheral set 403P and from regions 407 of the vias 101 of center set 403C. In this example, cavities 105P are located at a depth different from that of cavity 105C (a depth strictly less than that of cavity 105C, in the illustrated example). It comes from the fact that, differently from cavity 105C, the depth of cavities 105P was not set by a previous step of isotropically etching according to what was previously exposed in relation with FIGS. 1-3.

Although it was not described in detail, subsequent steps similar to, or same as, those previously described in relation with FIGS. 4G-4J are for example implemented from the structure shown in FIG. 6C. Implementing these steps results in obtaining a bulk acoustic wave filter having a structure similar to that of filter 400 hereinabove described in relation with FIG. 4J.

FIG. 7A and FIG. 7B illustrate, with schematic and partial side and section views, consecutive steps in an alternative to the method shown in FIGS. 4A-4J.

FIG. 7A is a schematic and partial side and section view illustrating a step for forming a plurality of vias 101 within semiconductor substrate 103, for example in a manner similar to or same as what was described in relation with FIGS. 4A-4B, then isotropically etching vias 101, for example in a manner similar to, or same as, what was described in relation with FIG. 4C. It results in forming partially spherical region 107 at the bottom of each via 101.

FIG. 7A further illustrates a subsequent step for anisotropically etching vias 101. For example, this step differs from that previously described in relation with FIG. 4D in that it is implemented during a longer time period. At the end of this step, each via 101 has a depth strictly higher than depth D1, for example higher than depth D3. By way of example, each via has a depth allowing, after annealing, four cavities to be formed from each via 101.

FIG. 7A further illustrates a subsequent step for isotropically etching vias 101, for example, in a manner similar to, or same as, what was previously described in relation with FIG. 4E. Isotropically etching results, in the illustrated example, in forming the partially spherical region 407 at the bottom of each via 101.

FIG. 7B is a schematic and partial side and section view illustrating a step for annealing semiconductor substrate 103. For example, the annealing step is implemented in a manner similar to what was described in relation with FIGS. 4F.

In the illustrated example, annealing results in obtaining the single cavity 105C from regions 107 of the vias 101 being part of center set 403C, and separate cavities 105P from regions 107 of the vias 101 being part of peripheral set 403P. Further, in this example, annealing results in obtaining the single cavity 405 from regions 407. Cavity 405 is more precisely formed from regions 407 of the vias 101 being part of center set 403C, and from regions 407 of the vias 101 being part of peripheral set 403P. In the illustrated example, annealing further results in obtaining for each vias 101, two cavities 705 substantially vertically aligned, and sandwiched between cavity 405 and cavity 105C, for cavities 705 obtained from the vias 101 of center set 403C, and between cavity 405 and overlaying cavity 105P, for cavities 705 obtained from the vias 101 of peripheral set 403P.

For example, each of cavities 705 is a buried or embedded air cavity within semiconductor substrate 103, and separate from other cavities 705, 105C, 105P, 405. Each cavity 705 is thus wholly included within semiconductor substrate 103, each cavity 705 being entirely closed.

Although it was not described in detail, subsequent steps similar to, or same as, those previously described in relation with FIGS. 4G-4J are for example implemented from the structure shown in FIG. 7B. Implementing these steps results in obtaining a bulk acoustic wave filter having a structure similar to that of filter 400 hereinabove described in relation with FIG. 4J. For example, the alternative shown in FIGS. 7A and 7B allows, at the end of a step similar to that previously described in relation with FIG. 4I, a depth of semiconductor substrate 103 to be kept higher than that obtained by implementing the methods hereinabove described in relation with FIGS. 4A-6C.

Moreover, although FIGS. 7A and 7B consider as example a case where each via 101 results, after annealing, in obtaining two superimposed cavities 705, this example is not a limitation, and those skilled in the art is more generally able, from the provisions of the present description, to provide to perform a non-zero integer number of cavities 705 from each via 101, in particular as a function of the target thickness of semiconductor substrate 103 he or she aims to obtain at the end of a step similar to that previously described in relation with FIG. 4I.

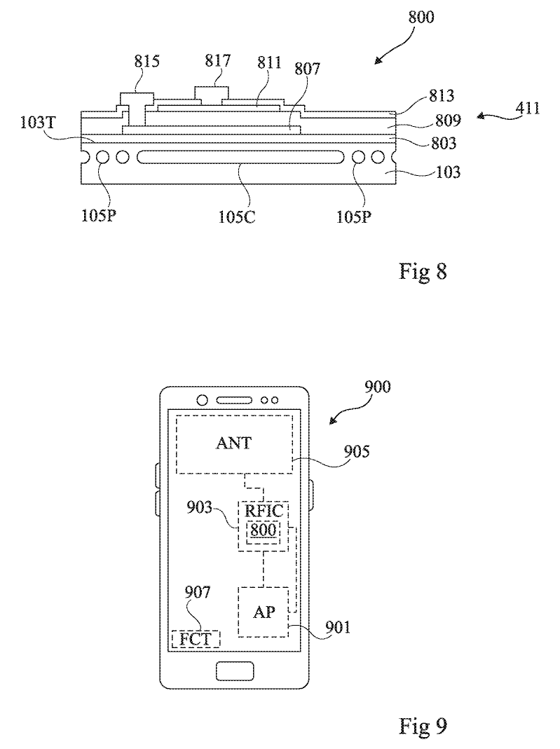

FIG. 8 is a schematic and partial side and section view of an example bulk acoustic wave filter 800 according to one embodiment.

In the illustrated example, filter 800 has a structure similar to that of one of the semiconductor chips 421 shown in FIG. 4I, but devoid of the protection cover 413 and conductive pillars 415. In this example, filter 800 comprises resonator 411.

In the illustrated example, filter 800 comprises an insulating layer 803 coating the top face 103T of semiconductor substrate 103. In the illustrated example, insulating layer 803 is located on, and in contact with, the whole top face 103T of semiconductor substrate 103. For example, insulating layer 803 has a thickness of between 1.3 and 4 µm. By way of example, insulating layer 803 is made of an oxide, such as silicon oxide. For example, insulating layer 803 acts as a passivating layer of the top face 103T of semiconductor substrate 103.

In the illustrated example, filter 800 further comprises an electrode 807 coating a part of the top face of insulating layer 803. In the illustrated example, electrode 807 is located on, and in contact with, a part of the top face of insulating layer 803. Electrode 807 is at least partially located directly above cavity 105C. As in the example illustrated in FIG. 8, electrode 807 is for example mainly located directly above cavity 105C. In this example, electrode 807 further comprises a minority part laterally extending out of line of cavity 105C. By way of example, electrode 807 is made of a conductive material, for example a metal such as aluminum or metal alloy.

In the illustrated example, filter 800 further comprises another insulating layer 809 coating side faces and the top face of electrode 807. In this example, insulating layer 809 further coats parts of the top face of insulating layer 803 not coated with electrode 807. In other words, insulating layer 809 laterally extends out of line of electrode 807. For example, insulating layer 809 is more precisely located on, and in contact with, side and top faces of electrode 807 and parts of the top face of insulating layer 803 not coated with electrode 807. By way of example, insulating layer 809 is a piezoelectric layer, i.e., a layer made of a piezoelectric material, for example Lithium Niobate Oxide (LNO), aluminum nitride, etc.

In the illustrated example, filter 800 further comprises another electrode 811 coating a part of the top face of insulating layer 809. In the illustrated example, electrode 811 is located on, and in contact with, a part of the top face of insulating layer 809. For example, electrode 811 is at least partially located directly above cavity 105C. As in the example illustrated in FIG. 8, electrode 811 is for example entirely located directly above cavity 105C. In this example, electrode 811 has lateral dimensions strictly smaller than those of electrode 807. By way of example, electrode 811 is made of a conductive material, e.g., a metal such as aluminum or a metal alloy. For example, electrode 811 is made of a same material as electrode 807.

For example, electrode 811 is asymmetrically shaped when viewed from above.

In the illustrated example, filter 800 further comprises another insulating layer 813 coating side faces and top face of electrode 811. In this example, insulating layer 813 further coats parts of the top face of the insulating layer 809 not coated with electrode 811. For example, insulating layer 813 is more precisely located on, and in contact with, side and top faces of electrode 811 and the parts of the top face of insulating layer 809 not coated with electrode 811. By way of example, insulating layer 813 is made of an oxide, such as silicon oxide. For example, insulating layer 813 is made of a same material as insulating layer 803. For example, insulating layer 813 acts as a passivating layer of the top face of the structure, in particular of electrode 811.

In the illustrated example, filter 800 further comprises contact-recovery elements 815 and 817 for electrodes 807 and 811, respectively. In the example illustrated in FIG. 8, contact-recovery element 815 is located on, and in contact with, a part of the top face of electrode 807 located out of line of cavity 105C. For example, when viewed in section, contact-recovery element 815 has a T-shape comprising a vertical part extending, from the top face of insulating layer 813, through insulating layers 813 and 809 to the top face of electrode 807 and a horizontal part laterally extending on, and in contact with, the top face of insulating layer 813 in the vicinity of the vertical part of contact-recovery element 815.

Furthermore, in this example, contact-recovery element 817 is located on, and in contact with, a part of the top face of electrode 811 located directly above cavity 105C. For example, when viewed in section, contact-recovery element 817 has a T-shape comprising a vertical part extending, from the top face of insulating layer 813, through insulating layer 813 to the top face of electrode 811 and a horizontal part laterally extending on, and in contact with, the top face of insulating layer 813 in the vicinity of the vertical part of contact-recovery element 817. Each contact-recovery element 815, 817 is made of a conductive material, such as a metal or a metal alloy. By way of example, contact-recovery elements 815 and 817 are made of a same material.

Although it was not illustrated in FIG. 8 in order not to overload the drawing, contact-recovery elements 815 and 817 are for example intended to be coupled or connected to one or more components or circuits outside filter 800. By way of example, contact-recovery elements 815 and 817 are intended to be connected to an RF communication circuit in an electronic device.

Electrodes 807 and 811 and the part of insulating layer 809 sandwiched between electrodes 807 and 811 are for example part of the resonator 411 of filter 800. For example, insulating layer 809 is referred to as active layer of the resonator 411 of filter 800, due to the fact that insulating layer 809 is intended to be excited by a signal applied on electrodes 807 and 811 arranged on either side of this layer.

For example, in operation, an RF signal is applied by contact-recovery elements 815 and 817, between electrodes 807 and 811 of filter 800. For example, an RF signal is an AC voltage. For example, applying, on electrodes 807 and 811, an RF signal causes an alternation of expansion and retraction phases of the insulating layer 809. It tends the resonator 411 of filter 800 to resonate and the membrane of filter 800 to vibrate. In a case where the RF signal has a frequency substantially equal to a resonant frequency of the membrane of filter 800, the RF signal is not, or is little, attenuated by filter 800. In contrast, in a case where the RF frequency has a frequency different from the resonant frequency of the membrane of filter 800, the RF signal is strongly attenuated by filter 800. For example, it allows avoiding interferences due to RF signals emitted from other electronic devices or noise from outer RF sources to perturb the operation of a channel for receiving RF communications of an electronic device.

FIG. 9 schematically and partially illustrates an example electronic device 900 integrating a bulk acoustic wave filter, such as filter 800 previously described in relation with FIG. 9. In the illustrated example, device 900 is a mobile phone or smartphone.

In this example, device 900 comprises a processing circuit 901 (AP), e.g., a microcontroller or a main microprocessor of device 900. For example, processing circuit 901 is connected to an RF integrated circuit 903 (RFIC) comprising at least one filter of the type of filter 400 or 800, such as filter 800. For example, filter 800 is integrated in a filtering electronic circuit, not described in detail in FIG. 9. In the illustrated example, RF integrated circuit 903 is connected to an antenna 905 (ANT), such as an RF communication antenna of device 900. Although it was not described in detail in FIG. 9 in order not to overload the drawing, RF integrated circuit 903 can further comprise components and circuits intended to implement functions of impedance matching, amplifying, modulating/demodulating, switching, etc.

Device 900 can further comprise other elements, for example other circuits or electronic components not described in detail in FIG. 9. These elements were symbolized in FIG. 9 by a functional block 907 (FCT).

Although FIG. 9 illustrates a case where filter 800 is integrated in device 900, this example is not a limitation, and those skilled in the art will be able, from the provisions of the present description, to provide to replace, in device 900 filter 800 with filter 400, or with a filter having a structure similar to that of filter 400 or 800.

Advantageously, filters 400 and 800 include a substrate 103 with a small thickness, for example a thickness at least twice smaller than that reachable using conventional technics for mechano-chemical polishing or grinding from the back face 103B of substrate 103. It allows filters 400 and 800 to be miniaturized. By way of example, the substrate 103 of filters 400 and 800 has a thickness smaller than 50 µm, such as smaller than 25 µm, e.g., smaller than 10 µm.

Various embodiments and variants have been described. Those skilled in the art will understand that certain features of these embodiments can be combined and other variants will readily occur to those skilled in the art. In particular, although FIGS. 4J and 8 consider as an example a case where filter 400, 800 comprises a single resonator 411 located above cavity 105C, those skilled in the art will be naturally able, based on the provisions of the present description, to replicate the embodiments shown in FIGS. 4J and 8 to any number of resonators located above a same cavity formed within a semiconductor substrate.

Based on the provisions of the present description, those skilled in the art will further be able to form several filters in a same semiconductor substrate, for example by providing forming several cavities buried in a same semiconductor substrate and at least one resonator located directly above each cavity.

Furthermore, although FIG. 9 considers as an example the case where filter 400 is integrated within a mobile phone or a smartphone, embodiments described are not limited to this example, but more generally apply to any device or system provided with wireless communication functions, for example in the field of telematics. Particularly, filter 400 or filter 800 could be integrated within motor vehicles, for example to implement functionalities of wirelessly access to Internet, communication between the vehicle and outer systems or equipment, autonomous driving, etc. for end applications such as managing vehicle fleets (location, motion, state, and behavior of each vehicle) or real-time navigation systems, or even to allow objects to communicate with a vehicle (for example as part of Internet of Things – IoT), without interference from systems not granted within a “circle” of authorized communication.

Finally, the practical implementation of the embodiments and variants described herein is within the capabilities of those skilled in the art based on the functional description provided hereinabove. In particular, forming filter 800 is within the capabilities of those skilled in the art based on the functional description provided hereinabove, particularly based on the method for manufacturing filter 400 described in relation with FIGS. 4A-4J.

Moreover, the described embodiments are not limited to the specific example materials or sizes stated in the present description.

1. A method for manufacturing a bulk acoustic wave filter comprising:
a) providing a semiconductor substrate;
b) forming first and second air cavities buried within the semiconductor substrate, the first air cavity being sandwiched between the second air cavity and a top face of the semiconductor substrate and having lateral dimensions smaller than those of the second air cavity; and
c) thinning the semiconductor substrate by forming trenches surrounding the first air cavity and opening into the second air cavity;
wherein steps a), b), and c) are performed consecutively.

2. The method according to claim 1, further comprising between steps a) and b), forming, within the semiconductor substrate, a first set of first vias and a second set of second vias surrounding the first set of first vias.

3. The method according to claim 2, wherein at step b), the first air cavity is formed from the first vias and the second air cavity is formed from the first and second vias.

4. The method according to claim 2, further comprising between steps a) and b):
forming the first and second vias by anisotropically etching the semiconductor substrate;
forming a first partially spherical region at a bottom of each via by isotropically etching the semiconductor substrate;
extending the first and second vias by anisotropically etching the semiconductor substrate; and
forming a second partially spherical region at the bottom of each via by isotropically etching the semiconductor substrate.

5. The method according to claim 2, further comprising between steps a) and b):
forming the first and second vias by anisotropically etching the semiconductor substrate; and
forming a partially spherical region at the bottom of each second via by isotropically etching the semiconductor substrate.

6. The method according to claim 2, further comprising between steps a) and b):
forming first vias by anisotropically etching the semiconductor substrate;
forming a first partially spherical region at the bottom of each first via by isotropically etching the semiconductor substrate;
extending the first vias by anisotropically etching the semiconductor substrate;
forming a second partially spherical region at the bottom of each first via by isotropically etching the semiconductor substrate;
forming the second vias by anisotropically etching the semiconductor substrate; and
forming a third partially spherical region at the bottom of each second via by isotropically etching the semiconductor substrate.

7. The method according to claim 1, further comprising at step b), forming from each of first and second vias, at least one third air cavity sandwiched between the first and second air cavities.

8. The method according to claim 1, further comprising at step b), forming from each second via, at least one fourth air cavity located within the semiconductor substrate, at a depth substantially equal to that of the first air cavity.

9. The method according to claim 1, further comprising between steps b) and c), fabricating at least one resonator directly above the first air cavity, each resonator comprising an active layer sandwiched between a bottom electrode and a top electrode.

10. The method according to claim 1, wherein, at step b), the first air cavity and the second air cavity are formed by annealing the semiconductor substrate under a hydrogen atmosphere.

11. A bulk acoustic wave filter comprising:
a semiconductor substrate in which first and second air cavities are formed buried within the semiconductor substrate, the first air cavity being sandwiched between the second air cavity and a top face of the semiconductor substrate and having lateral dimensions smaller than those of the second air cavity; wherein the semiconductor substrate is thinned by forming trenches surrounding the first air cavity and opening into the second air cavity.

12. The filter according to claim 11, wherein the first air cavity is located, within the semiconductor substrate, at a depth of between 300 nm and 1.5 µm.

13. The filter according to claim 11, wherein the semiconductor substrate has, after thinning, a thickness less than 50 µm.

14. The filter according to claim 11, wherein the semiconductor substrate has, after thinning, a thickness less than 25 µm.

15. The filter according to claim 11, wherein the semiconductor substrate has, after thinning, a thickness less than 10 µm.

16. The filter according to claim 11, wherein a first set of first vias and a second set of second vias surrounding the first set of first vias is formed within the semiconductor substrate.

17. The filter according to claim 16, wherein the first air cavity is formed from the first vias and the second air cavity is formed from the first and second vias.

18. The filter according to claim 16, wherein the first and second vias are formed by anisotropically etching the semiconductor substrate;
wherein a first partially spherical region is formed at a bottom of each via by isotropically etching the semiconductor substrate;
wherein the first and second vias are extended by anisotropically etching the semiconductor substrate; and
wherein a second partially spherical region is formed at the bottom of each via by isotropically etching the semiconductor substrate.

19. The filter according to claim 11, wherein the semiconductor substrate further comprises at least one resonator directly above the first air cavity, each resonator comprising an active layer sandwiched between a bottom electrode and a top electrode.

20. An electronic device comprising:
a radio frequency integrated circuit including at least one filter, the filter comprising:
a semiconductor substrate in which first and second air cavities are formed buried within the semiconductor substrate, the first air cavity being sandwiched between the second air cavity and a top face of the semiconductor substrate and having lateral dimensions smaller than those of the second air cavity; wherein the semiconductor substrate is thinned by forming trenches surrounding the first air cavity and opening into the second air cavity.
